(19) United States
(12) Patent Application Publication
(10) Pub. No.: US 2013/0134926 A1
(43) Pub. Date: May 30, 2013

(54) BATTERY MANAGEMENT APPARATUS AND BATTERY MANAGEMENT METHOD

(71) Applicant: Kenji Yoshida, Kumagaya-shi (JP)

(72) Inventor: Kenji Yoshida, Kumagaya-shi (JP)

(21) Appl. No.: 13/536,850

(22) Filed: Jun. 28, 2012

(30) Foreign Application Priority Data
Nov. 30, 2011 (JP) 2011-262863

(51) Int. Cl. G01R 31/36; H02J 7/00

(52) U.S. Cl. 320/107; 324/426

(57) ABSTRACT

According to one embodiment, a battery management apparatus includes a time measurement module and a determination module. The time measurement value is configured to measure a discharge time after requesting driving a device by a direct-current voltage supplied from the battery until the voltage is lowered to a discharge stop voltage which is a voltage that the battery should stop discharge. The determination module is configured to determine that the battery is new, when the discharge time measured by the time measurement module is greater than or equal to a predetermined time that is set to determine if the battery is new.

### CROSS-REFERENCE TO RELATED APPLICATIONS

This application is based upon and claims the benefit of priority from prior Japanese Patent Application No. 2011-262863, filed Nov. 30, 2011, the entire contents of which are incorporated herein by reference.

### FIELD

Embodiments described herein relate generally to battery management apparatus and a battery management method that manage a rechargeable battery that cannot be individually identified.

### BACKGROUND

As well known, in recent years, there has been considered that a rechargeable battery is mounted in not only a mobile electronic device but also a stationary electronic device, the battery is charged in a time zone that a demand for electric power has leeway, the electric device is driven by the power of the battery in a time zone that power consumption reaches a peak, and a time zone that the power consumption is high is thereby shifted so that the demand for electric power is decentralized.

Meanwhile, there are two types of battery, i.e., one that has intrinsic identifying information and hence can be individually identified and one that cannot be individually identified. In the battery that can be individually identified of these batteries, since its history information concerning charge and discharge can be saved in association with the identifying information, and hence a time to replace and others can be determined based on a deterioration condition of performance of the battery.

On the other hand, in the battery that cannot be individually identified, since its history information concerning charge and discharge cannot be stored, it is difficult to grasp a deterioration condition of performance and determine a time to replace. Under the present circumstances, for example, a user generally feels that a cycle of charge and discharge has become short and determines a time to replace the battery.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1A and FIG. 1B are exterior drawings for explaining an example of a digital television broadcast receiver as an embodiment;

FIG. 2 is a block diagram for roughly explaining an example of an example of a signal processing system in the digital television broadcast receiver according to the embodiment;

FIG. 3 is a block diagram for explaining a power supply module provided in the digital television broadcast receiver according to the embodiment;

FIG. 4 is a characteristic view for explaining an example of a battery for use in the digital television broadcast receiver according to the embodiment;

FIG. 5 is a flowchart for explaining a part of an example of a processing operation for measuring a discharge time of the battery performed by the digital television broadcast receiver according to the embodiment;

FIG. 6 is a flowchart for explaining a remaining part of the example of the processing operation for measuring a discharge time of the battery performed by the digital television broadcast receiver according to the embodiment;

FIG. 7 is a flowchart for explaining a part of an example of a processing operation for measuring a discharge time of the battery with a light load performed by the digital television broadcast receiver according to the embodiment;

FIG. 8 is a flowchart for explaining a remaining part of the processing operation for measuring a discharge time of the battery with a light load performed by the digital television broadcast receiver according to the embodiment;

FIG. 9 is a flowchart for explaining an example of a primary processing operation performed by the digital television broadcast receiver according to the embodiment;

FIG. 10 is a flowchart for explaining another part of the example of the primary processing operation performed by the digital television broadcast receiver according to the embodiment; and

FIG. 11 is a flowchart for explaining a remaining part of the example of the primary processing operation performed by the digital television broadcast receiver according to the embodiment.

### DETAILED DESCRIPTION

Various embodiments will be described hereinafter with reference to the accompanying drawings. In general, according to one embodiment, a battery management apparatus comprises a time measurement module and a determination module. The time measurement value is configured to measure a discharge time after requesting driving a device by a direct-current voltage supplied from the battery until the voltage is lowered to a discharge stop voltage which is a voltage that the battery should stop discharge. The determination module is configured to determine that the battery is new, when the discharge time measured by the time measurement module is greater than or equal to a predetermined time that is set to determine if the battery is new.

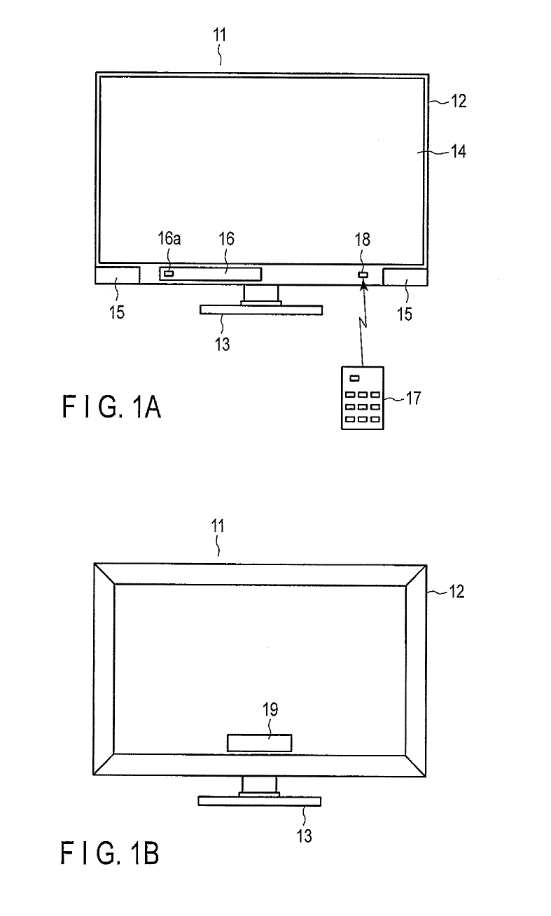

FIG. 1A shows an example of a digital television broadcast receiver 11 described in this embodiment seen from a front side. This digital television broadcast receiver 11 is constituted of a thin cabinet 12 and a support platform 13 that erects and supports this cabinet 12.

Further, a video display panel 14 as a video display module is arranged in a front central part of the cabinet 12. Furthermore, a pair of speakers 15, 15, an operation module 16 including a main power supply switch 16a, and a light receiver 18 configured to receive operating information transmitted from a remote controller 17 are arranged in a lower part of a front surface of the cabinet 12.

FIG. 1B shows an example of the digital television broadcast receiver 11 seen from a back side. In this case, a battery attachment module 19 is provided in a lower part of the cabinet 12 on the back side. A rechargeable battery (not shown) is detachable from/attachable to this battery attachment module 19.

Additionally, the digital television broadcast receiver 11 can charge the battery attached to this battery attachment module 19. Further, the digital television broadcast receiver 11 receives power from the battery attached to this battery attachment module 19, and it is driven.

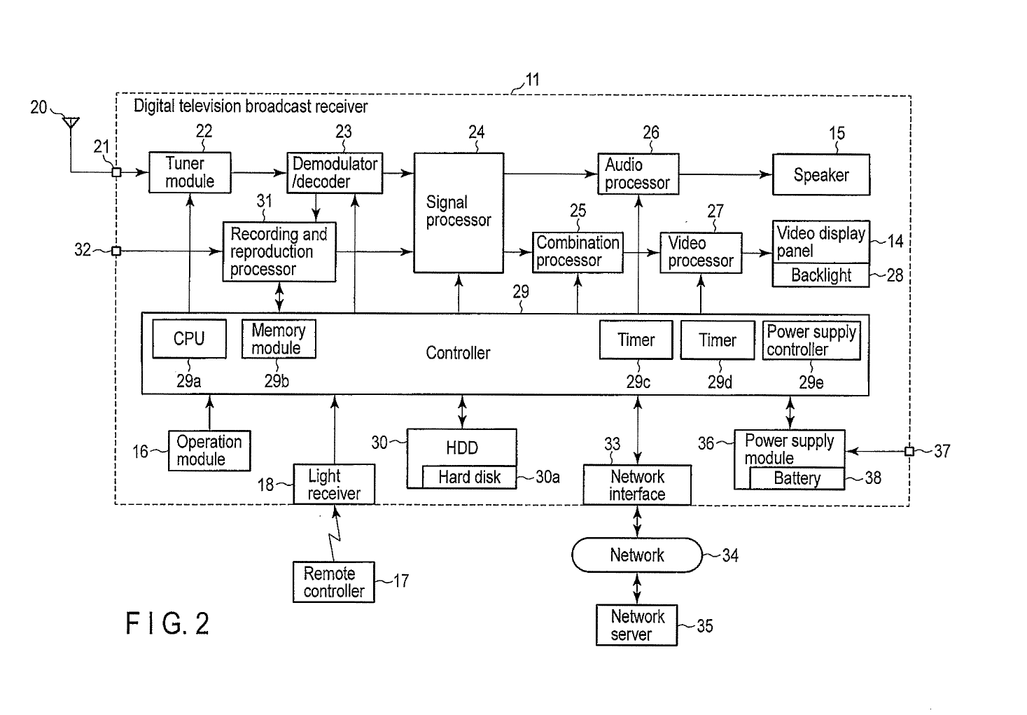

FIG. 2 schematically shows an example of a signal processing system of the digital television broadcast receiver 11. That is, a digital television broadcast signal received by an antenna 20 is supplied to a tuner module 22 through an input terminal 21, and a broadcast signal of a desired channel is thereby selected.

The broadcast signal selected by this tuner module 22 is supplied to a demodulator/decoder 23, restored to, for example, a digital video signal and a digital audio signal, and then output to a signal processor 24. This signal processor 24 performs predetermined digital signal processing with respect to each of the digital video signal and the digital audio signal supplied from the demodulator/decoder 23.

Furthermore, this signal processor 24 outputs the digital video signal to a combination processor 25 and outputs the digital audio signal to a audio processor 26. Of these members, the combination processor 25 superimposes an on-screen display (OSD) signal on the digital video signal supplied from the signal processor 24 and outputs the obtained signal.

This digital video signal output from this combination processor 25 is supplied to a video processor 27, converted into an analog video signal having a predetermined format, and then used for formation of a video in the video display panel 14 formed of, for example, liquid crystal. Furthermore, when this video display panel 14 is irradiated with illumination light from a backlight 28 using a light emitting diode (LED) or the like as a light source, a video is displayed.

Moreover, the audio processor 26 converts the input digital audio signal into an analog audio signal having a format that is reproducible by the speaker 15 provided in a latter stage. Additionally, the analog audio signal output from this audio processor 26 is supplied to the speaker 15, and hence it is used for reproduction of audio.

Here, all operations of this digital television broadcast receiver 11, which include various receiving operations mentioned above, are collectively controlled by a controller 29. This controller 29 has a built-in central processing unit (CPU 29a), receives operating information from the operation module 16, or receives operating operation transmitted from the remote controller 17 and received by the light receiver 18, and controls the respective modules so that operation contents can be reflected.

In this case, the controller 29 utilizes a memory module 29b. This memory module 29b mainly has a read-only memory (ROM) storing a control program executed by the CPU 29a, a random access memory (RAM) that provides the CPU 29a with a work area, and a nonvolatile memory that stores various kinds of setting information, control information, and others.

Additionally, this controller 29 is connected with a hard disk drive (HDD) 30. This controller 29 can perform control in such a manner that a digital video signal and a digital audio signal obtained from the demodulator/decoder 23 can be encrypted by a recording and reproduction processor 31 and converted into predetermined recording formats based on an operation of the operation module 16 or the remote controller 17 by a user and then these signals can be supplied to the HDD 30 and recorded in a hard disk 30a.

Further, this controller 29 can perform control in such a manner that a digital video signal and a digital audio signal can be read from the hard disk 30a by the HDD 30 and decoded by the recording and reproduction processor 31 based on an operation of the operation module 16 or the remote controller 17 by a user and then these signals can be supplied to the signal processor 24 and subsequently used for the display of a video and the reproduction of audio.

Furthermore, an input terminal 32 is connected to the recording and reproduction processor 31. This input terminal 32 is used for directly inputting a digital video signal and a digital audio signal from the outside of the digital television broadcast receiver 11. The digital video signal and the digital audio signal input through this input terminal 32 are supplied to the signal processor 24 through the recording and reproduction processor 31 and then used for the display of a video and the reproduction of audio based on control of the controller 29.

Moreover, the digital video signal and the digital audio signal input through this input terminal 32 are transmitted through the recording and reproduction processor 31 based on control of the controller 29 and then used for recording and reproduction with respect to the hard disk 30a by the HDD 30.

Additionally, a network interface 33 is connected to the controller 29. This network interface 33 is connected to an external network 34. Further, to this network 34 is connected a network server 35 which is configured to utilize a communicating function through the network 34 and provide various kinds of services.

Therefore, the controller 29 accesses a network server 35 through the network interface 33 and the network 34 based on an operation of the operation module 16 or the remote controller 17 by a user and performs information communication, whereby provided services are available.

Furthermore, a power supply module 36 is connected to the controller 29. A commercial alternating-current (AC) power distributed for domestic use by an electric power company is supplied to this power supply module 36 through a power supply terminal 37. Moreover, this power supply module 36 functions to supply necessary electric power to respective modules 14 to 16, 18, 22 to 31, 33, and others constituting the digital television broadcast receiver 11 based on the AC power supplied to the power supply terminal 37 based on control of the controller 29.

In this case, the power supply module 36 includes the battery attachment module 19. Additionally, this power supply module 36 can charge a battery 38 attached to the battery attachment module 19 with the AC power supplied through the power supply terminal 37 or supply the charge power in this battery 38 to the respective modules in place of the AC power supplied to the power supply terminal 37. In this case, as the battery 38, for example, a lithium-ion battery is used, and a battery which cannot be individually identified is assumed.

Further, the controller 29 includes timers 29c and 29d and a power supply controller 29e. Of these members, each of timers 29c and 29d is used for acquisition of a current time or a timing operation for measuring a time path. Furthermore, as will be described later in detail, the power supply controller 29e controls operations in the power supply module 36.

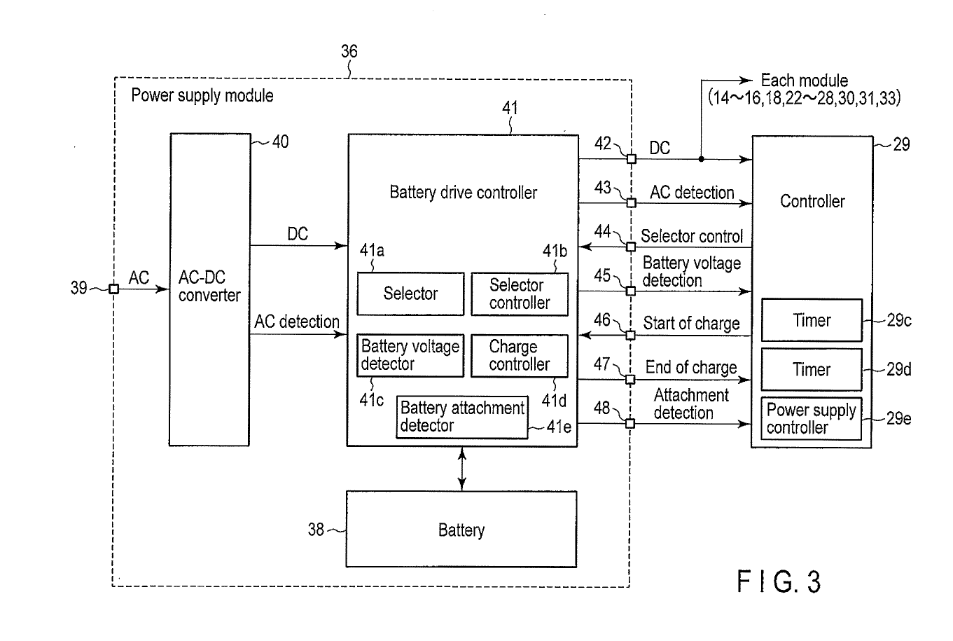

FIG. 3 shows an example of the power supply module 36. This power supply module 36 includes an input terminal 39 to which the AC power is supplied through the power supply terminal 37. The AC power supplied to this input terminal 39 is supplied to an AC-DC converter 40.

This AC-DC converter 40 converts the input AC power into direct-current (DC) power of a predetermined level and outputs the converted power to a battery drive controller 41. Furthermore, this AC-DC converter 40 detects a state where the AC power is supplied to the input terminal 39 or a state that the AC power is not supplied to the input terminal 39 due to, for example, electric outage, generates an AC detection signal indicative of this detection result, and outputs this signal to the battery drive controller 41.

This battery drive controller 41 functions to selectively lead DC power supplied from the AC-DC converter 40 and DC power supplied from the battery 38 to an output terminal 42 by a selector 41a. Moreover, the DC power taken from this output terminal 42 is supplied to the controller 29 constituting the digital television broadcast receiver 11 and also supplied to the other respective modules 14 to 16, 18, 22 to 28, 30, 31, and 33.

In this case, the battery drive controller 41 outputs an AC detection signal supplied from the AC-DC converter 40 to the controller 29 from the output terminal 43. When the input AC detection signal indicates that the AC power is not supplied to the input terminal 39, the power supply controller 29e of the controller 29 outputs a selector control signal for switching the selector 41 so that the DC power output from the battery 38 can be led to the output terminal 42. This selector control signal is supplied to a selector controller 41b of the battery drive controller 41 through an input terminal 44, and it is used for switching the selector 41a.

As described above, in a state that the digital television broadcast receiver 11 is driven by the DC power output from the battery 38, a drive time, i.e., a discharge time of the battery 38 is measured by timer 29c of the controller 29.

Further, when the input AC detection signal indicates that the AC power is supplied to the input terminal 39, the power supply controller 29e of the controller 29 outputs a selector control signal for switching the selector 41a so that the DC power output from the AC-DC converter 40 can be led to the output terminal 42. This selector control signal is supplied to the selector controller 41b of the battery drive controller 41 through the input terminal 44, and it is used for switching the selector 41a.

It is to be noted that, even in a state that the digital television broadcast receiver 11 is driven by the DC power output from the AC-DC converter 40, when the DC power of the battery 38 is used for detection of a voltage in a later-described battery voltage detector 41c or charge controller 41d, this power is consumed. Further, a discharge time of the battery 38 when a load is light is measured by timer 29d of the controller 29.

Furthermore, the battery drive controller 41 detects an output DC voltage of the battery 38 by the battery voltage detector 41c and outputs a battery voltage detection signal indicative of this detection result to the controller 29 from an output terminal 45. The power supply controller 29e of the controller 29 analyzes the input voltage detection signal, and it outputs a charge start signal if it determines that the battery 38 needs to be charged.

When this charge start signal is supplied to the charge controller 41d of the battery drive controller 41 through an input terminal 46, the charge controller 41d supplies the DC power output from the AC-DC converter 40 to the battery 38 and starts charging the battery 38. In this case, if a power supply capability of the AC-DC converter 40 is sufficiently high, the DC power output from the AC-DC converter 40 can be used for driving the digital television broadcast receiver 11 and charging the battery 38 at the same time but, in general, safety is taken into consideration, and the battery 38 is charged when the digital television broadcast receiver 11 is not driven, i.e., when a television broadcast program is not watched.

It is to be noted that, when the charge controller 41d has detected that the battery 38 is fully charged, this controller outputs a charge completion signal. When this charge completion signal is supplied to the controller 29 through an output terminal 47, the power supply controller 29e of the controller 29 functions to stop output of the charge start signal and also stop charge.

Moreover, the battery drive controller 41 comprises a battery attachment detector 41e. This battery attachment detector 41e detects that the battery 38 is attached to the battery attachment module 19 and outputs a battery attachment signal. When this battery attachment signal is supplied to the controller 29 through an output terminal 48, the power supply controller 29e of the controller 29 recognizes the attachment of the battery 38.

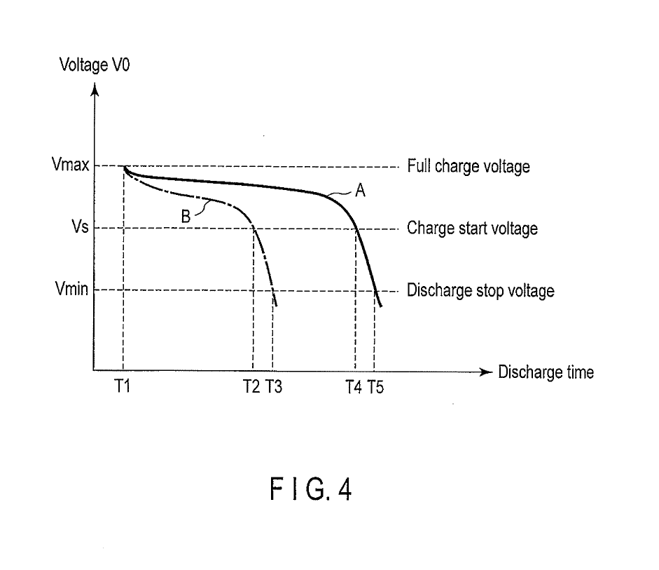

FIG. 4 shows an example of discharge characteristics of the battery 38 when the digital television broadcast receiver 11 is driven by the DC power output from the battery 38. It is to be noted that characteristics A indicated by a solid line in FIG. 4 represent discharge characteristics of the new battery 38 whose performance as a battery is not deteriorated, and characteristics B indicated by an alternate short and long dash line represent discharge characteristics of the battery 38 whose performance as a battery is deteriorated and which should be replaced with a new product.

First, when discharge of the new battery 38 charged to a full charge voltage Vmax is started at time T1, an output voltage V0 of the battery 38 is reduced to a charge start voltage Vs that should be subjected to charge at time T4, and then this voltage reaches a discharge stop voltage Vmin that should be stopped from being discharged at time T5. Here, the discharge stop voltage Vmin means a voltage that is set to avoid further discharge so that charge and discharge characteristics of the rechargeable battery 38 can be maintained without being deteriorated as much as possible.

On the other hand, when the battery 38 that is charged to the full charge voltage Vmax and immediately before replacement begins to be discharged at time T1, the output voltage V0 from the battery 38 is reduced to the charge start voltage Vs that should be subjected to charge at time T2 that is ahead of time T4, and then this voltage reaches the discharge stop voltage Vmin that should be stopped from being discharged at time T3 that is ahead of time T5.

That is, when discharge of the battery 38 is started from the same full charge voltage Vmax, a time to reach the charge start voltage Vs or the discharge stop voltage Vmin becomes shorter as the performance of this battery is deteriorated. Additionally, this matter can be likewise observed at the time of a light load described above.

Therefore, when a discharge time of the battery 38 is measured and the measured discharge time is compared with a predetermined discharge time that is set in advance to determine whether the battery 38 is new or a predetermined discharge time that is set in advance to determine when the battery 38 should be replaced, it is possible determine whether this battery 38 is new or whether the battery 38 has reached a time for replacement, and the battery 38 can be managed.

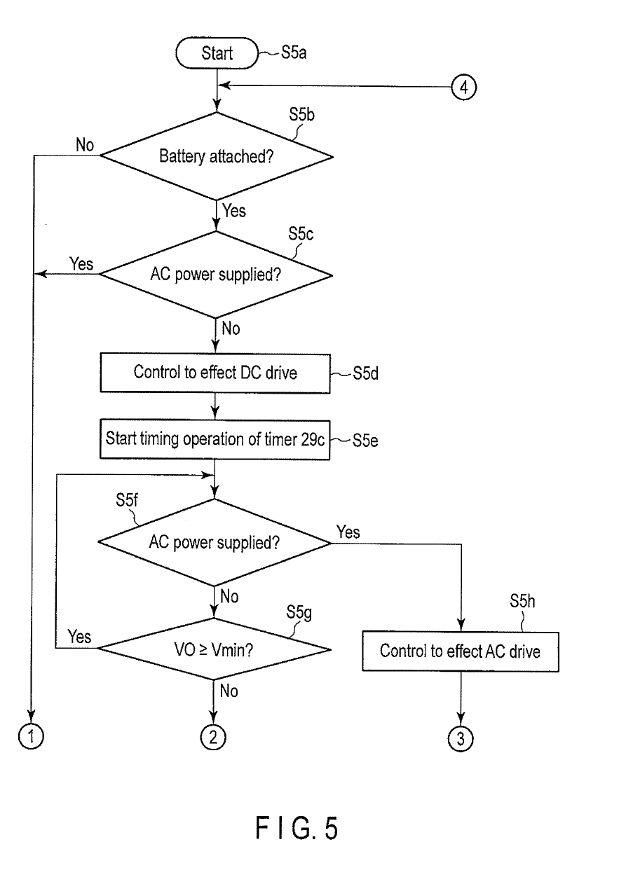

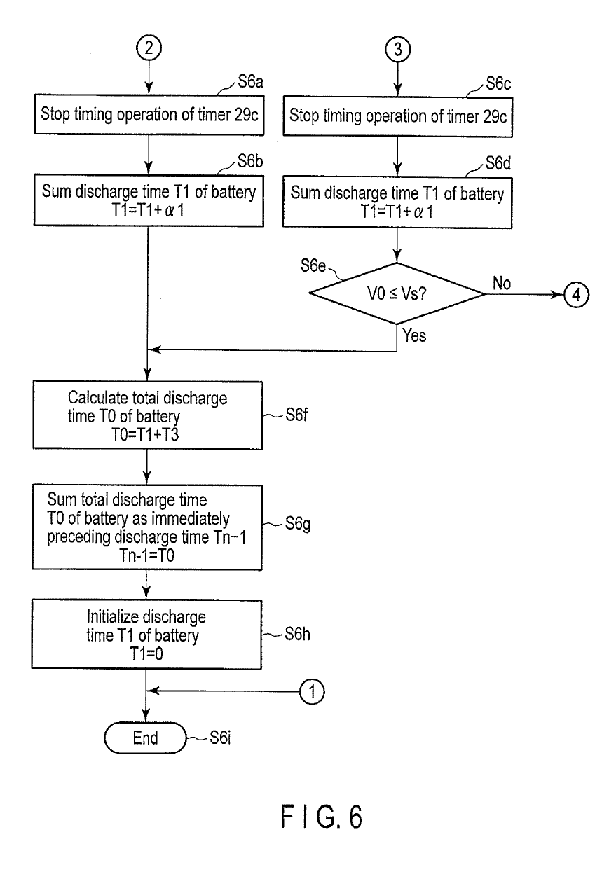

Therefore, FIG. 5 and FIG. 6 show flowcharts that sum up a processing operation of the power supply controller 29e of the controller 29 for measuring a discharge time of the battery 38 using timer 29c when the digital television broadcast receiver 11 is driven by the DC power output from the battery 38.

That is, when the processing starts (step S5a), the power supply controller 29e determines whether the battery 38 is attached to the battery attachment module 19 in step S5b, and it terminates the processing (step S6i) when it is determined that the battery 38 is not attached (NO).

Further, when it is determined that the battery 38 is attached to the battery attachment module 19 in step S5b (YES), the power supply controller 29e determines whether the AC power from the outside is supplied to the power supply module 36 in step S5c, and it terminates the processing (step S6i) when it is determined that the power is supplied (YES).

On the other hand, when it is determined that the AC power from the outside is not supplied to the power supply module 36 in step S5c (NO), the power supply controller 29e controls in such a manner that the digital television broadcast receiver 11 is driven by the DC power from the battery 38, i.e., that the digital television broadcast receiver 11 is DC-driven in step S5d.

Then, the power supply controller 29e allows timer 29c to start a timing operation in step S5e, and it determines whether the AC power from the outside is supplied to the power supply module 36 in step S5f.

Furthermore, when it is determined that the AC power is not supplied (NO), the power supply controller 29e determines whether the output voltage V0 of the battery 38 is not lower than the discharge stop voltage Vmin in step S5g, and the control is returned to the processing of step S5f when it is determined that V0≧Vmin is achieved (YES).

Moreover, when it is determined that V0≧Vmin is not achieved in step S5g (NO), the power supply controller 29e stops the timing operation of timer 29c in step S6a, and it adds a timing result α1 of timer 29c as a discharge time T1 of the battery 38 in step S6b.

On the other hand, when it is determined that AC power from the outside is supplied to the power supply module 36 in step S5f (YES), the power supply controller 29e controls in such a manner that the digital television broadcast receiver 11 is driven by the AC power from the outside, i.e., that the digital television broadcast receiver 11 is AC-driven in step S5h.

Additionally, the power supply controller 29e stops the timing operation of timer 29c in step S6c, and it adds the timing result α1 of timer 29c as discharge time T1 of the battery 38 in step S6d. Thereafter, the power supply controller 29e determines whether the output voltage V0 of the battery 38 is not greater than a charge start voltage Vs in step S6e, and the control is returned to the processing of step S5b when it is determined that V0≧Vs is not achieved.

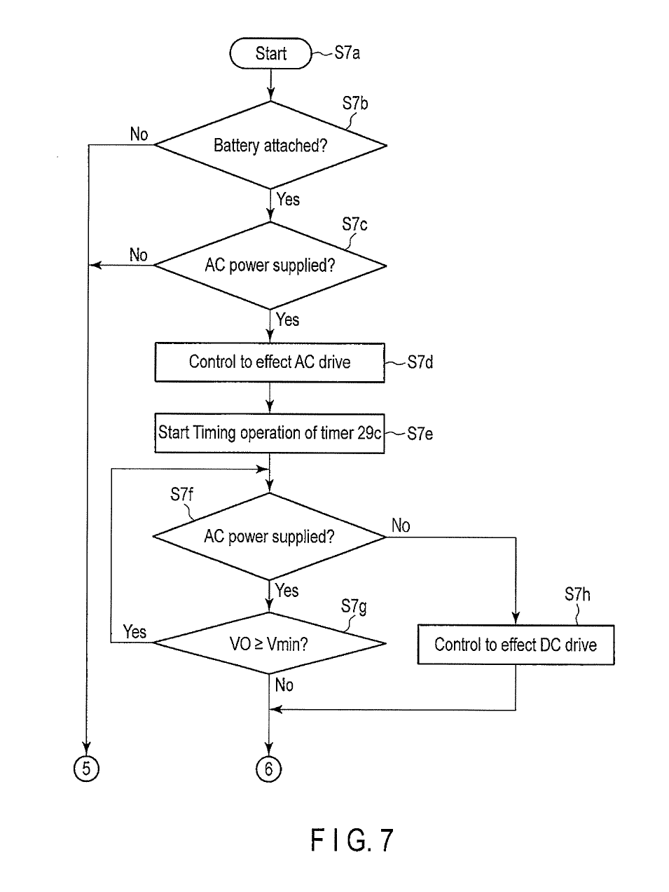

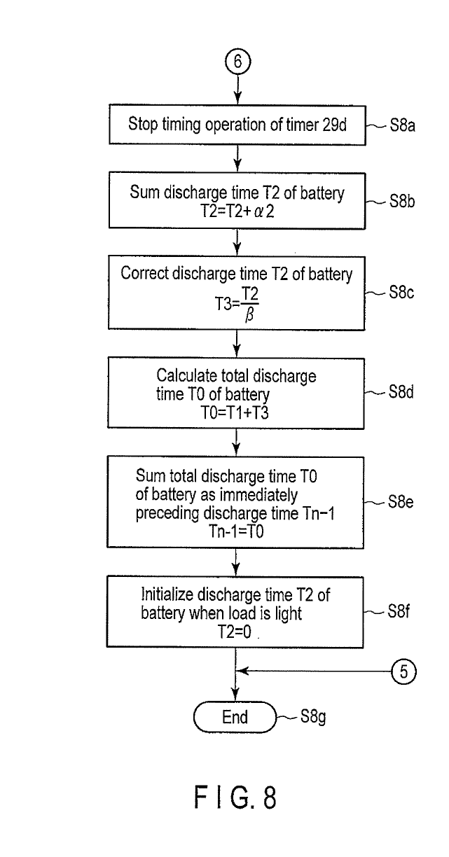

Further, after step S6b, or when it is determined that V0≦Vs is achieved (YES) in step S6e, the power supply controller 29e calculates a total discharge time T0=T1+T3 which is obtained by adding discharge time T1 of the battery 38 when the digital television broadcast receiver 11 is DC-driven and discharge time T3 of the battery 38 when the digital television broadcast receiver 11 is AC-driven, i.e., at the time of a light load (which will be explained with reference to FIG. 7 and FIG. 8) in step S6f.

Thereafter, the power supply controller 29e aggregates the total discharge time T0 of the battery 38 as a previous discharge time Tn−1 in step S6g, and it initializes discharge time T1 of the battery 38 in step S6h and terminates the processing (step S6i).

Furthermore, FIG. 7 and FIG. 8 show flowcharts that sum up a processing operation of the power supply controller 29e in the controller 29 for measuring a discharge time of the battery 38 using timer 29d in a state that the digital television broadcast receiver 11 is driven by the AC power supplied from the outside, i.e., that a light load is applied to the battery 38.

That is, when the processing starts (step S7a), the power supply controller 29e determines whether the battery 38 is attached to the battery attachment module 19 in step S7b, and the processing is terminated (step S8g) when it is determined that the battery 38 is not attached (NO).

Further, when it is determined that the battery 38 is attached to the battery attachment module 19 in step S7b (YES), the power supply controller 29e determines whether the AC power from the outside is supplied to the power supply module 36 in step S7c, and the processing is terminated (step S8g) when it is determined that the AC power is not supplied (NO).

On the other hand, when it is determined that the AC power from the outside is supplied to the power supply module 36 in step S7c (YES), the power supply controller 29e controls in such a manner that the digital television broadcast receiver 11 is driven by the AC power supplied from the outside, i.e., that the digital television broadcast receiver 11 is AC-driven in step S7d.

Then, the power supply controller 29e allows timer 29d to start a timing operation in step S7e and determines whether the AC power from the outside is supplied to the power supply module 36 in step S7f.

Furthermore, when it is determined that the AC power is supplied (YES), the power supply controller 29e determines whether the output voltage V0 of the battery 38 is not lower than the discharge stop voltage Vmin, and the control is returned to the processing of step S7f when it is determined that V0≧Vmin is attained (YES).

Moreover, when it is determined that the AC power is not supplied in step S7f (NO), the power supply controller 29e controls in such a manner that the digital television broadcast receiver 11 is driven by the DC power of the battery 38, i.e., that the digital television broadcast receiver 11 is DC-driven in step S7h.

Additionally, after this step S7h, or when it is determined that V0≧Vmin is not achieved in step S7g (NO), the power supply controller 29e stops the timing operation of timer 29d in step S8a and adds a timing result α2 of timer 29d as a discharge time T2 when a light load is imposed on the battery 38 in step S8b.

Subsequently, in step S8c, the power supply controller 29e calculates a discharge time T3 which is obtained by correcting discharge time T2 at the time of the light load to be converted into a discharge time at the time of the DC drive. This discharge time T3 can be obtained by dividing discharge time T2 presented at the time of a light load by a correction value β previously calculated based on measured values of the discharge voltage and the discharge time at the time of DC drive and measured values of the discharge voltage and the discharge time at the time of the light load.

Further, in step S8d, the power supply controller 29e calculates a total discharge time T0=T1+T3 obtained by adding discharge time T1 of the battery 38 when the digital television broadcast receiver 11 is DC-driven and discharge time T3 of the battery 38 when the digital television broadcast receiver 11 is AC-driven, i.e., at the time of the light load.

Then, the power supply controller 29e aggregates the total discharge time T0 of the battery 38 as a previous discharge time Tn−1 in step S8e, and it initializes discharge time T2 of the battery 38 at the time of a light load in step S8f and terminates the processing (step S8g).

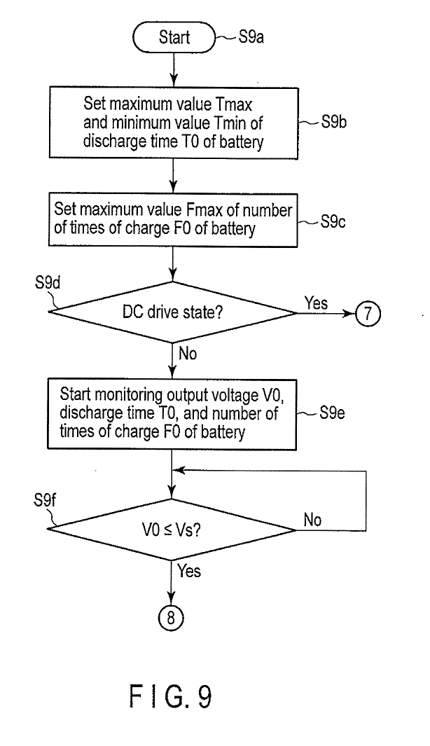

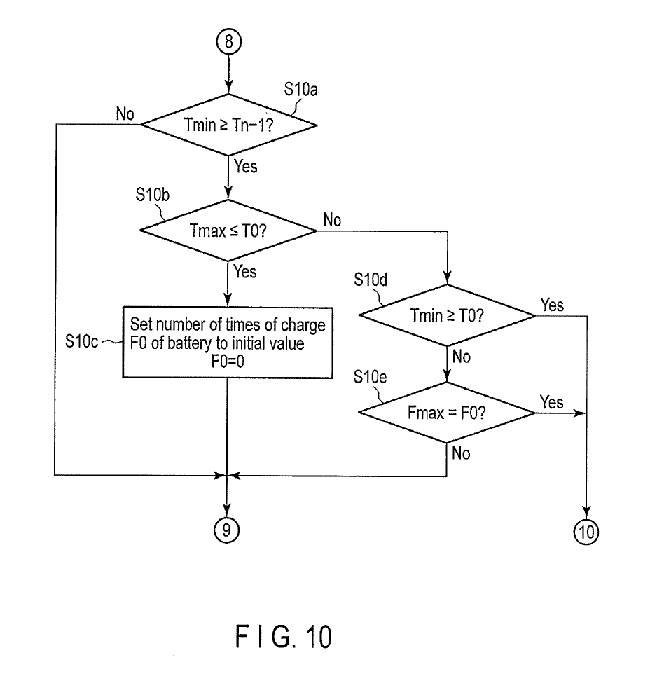

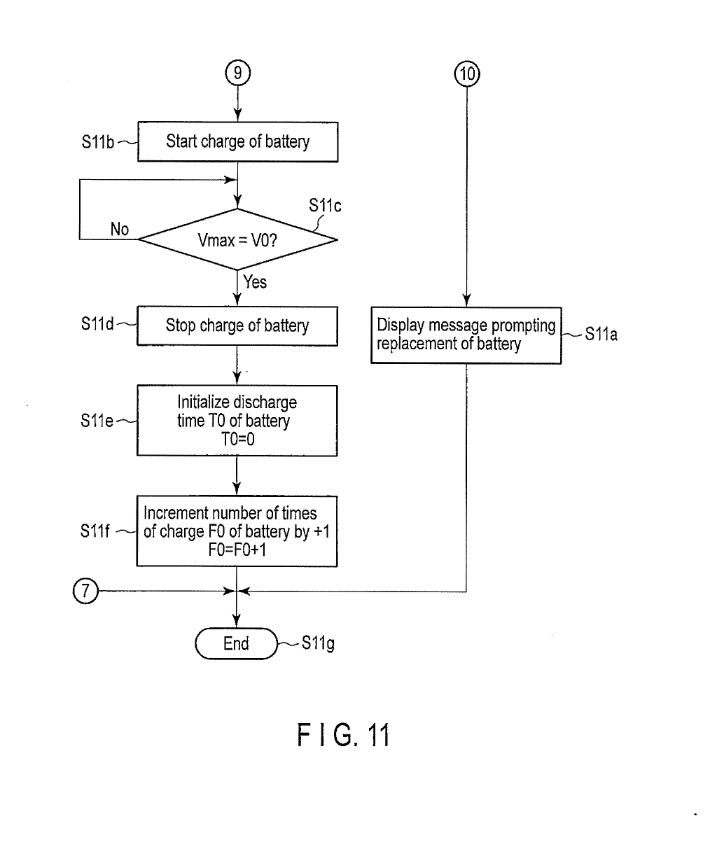

Subsequently, FIG. 9 to FIG. 11 show flowcharts that sum up a processing operation of the power supply controller 29e of the controller 29 for managing the battery 38 at the time of AC drive using the thus obtained discharge time T0 of the battery 38.

That is, when the processing starts (step S9a), the power supply controller 29e sets a maximum value Tmax and a minimum value Tmin of the discharge time of the battery 38 in step S9b. Of these values, the maximum value Tmax is set in accordance with a discharge time required for the new battery 38 to reach the discharge stop voltage Vmin from the full charge voltage Vmax. Furthermore, the minimum value Tmin is set in accordance with a discharge time that is required for the battery 38, whose performance has been deteriorated and which has reached a time for replacement, to reach the discharge stop voltage Vmin from the full charge voltage Vmax.

Then, in step S9c, the power supply controller 29e sets a maximum value Fmax of the number of times of charging the battery 38. This maximum value Fmax is set in accordance with the number of times of charge that a user is urged to replace the battery 38.

Moreover, in step S9d, the power supply controller 29e determines whether the digital television receiver 11 is driven by the DC power of the battery 28, i.e., whether the digital television broadcast receiver 11 is in a DC drive state, and the processing is terminated (step S11g) when it is determined that the digital television broadcast receiver 11 is in the DC drive state (YES). This determination of the DC drive state is performed when the power supply controller 29c analyzes an AC detection signal generated by the AC-DC converter 40 and supplied through the battery drive controller 41.

Additionally, when it is determined that the digital television broadcast receiver 11 is not in the DC drive state in step S9d (NO), the power supply controller 29e starts monitoring the output voltage V0, discharge time T0, and the number of times of charge F0 of the attached battery 38 in step S9e.

Of these items, the output voltage V0 of the battery 38 can be obtained when the power supply controller 29e analyzes a battery voltage detection signal output from the battery voltage detector 41c of the battery drive controller 41. Furthermore, discharge time T0 of the battery 38 can be obtained by the technique described with reference to, for example, the flowcharts shown in FIG. 5 and FIG. 6 and the flowcharts shown in FIG. 7 and FIG. 8. Moreover, the number of times of charge F0 of the battery 38 can be obtained from the number of times of performing later-described charge start processing.

Then, the power supply controller 29e determines whether the output voltage V0 of the battery 38 is not greater than the charge start voltage Vs in step S9f, and waits until V0≦Vs is achieved when it is determined that V0≦Vs is not attained (NO), or determines whether the immediately preceding discharge time Tn−1 of the battery 38 is not greater than the minimum value Tmin of the discharge time in step S10a when it is determined that V0≦Vs is achieved (YES).

Additionally, the power supply controller 29e determines whether discharge time T0 of the battery 38 is not smaller than the maximum value Tmax in step S10b when it is determined that Tmin≧Tn−1 is achieved (YES), or it determines that the battery 38 is new and sets the number of times of charge of the battery 38 to an initial value in step S10c when it is determined that Tmax≦T0 is achieved (YES).

Further, the power supply controller 29e determines whether discharge time T0 of the battery 38 is not greater than the minimum value Tmin of the discharge time in step S10d when it is determined that Tmax≦T0 is not achieved in step S10b (NO), or it determines whether the number of times of charge F0 of the battery 38 has reached the maximum value Fmax in step S10e when it is determined that Tmin≧T0 is not achieved (NO).

Furthermore, when it is determined that Tmin≧T0 is achieved in step S10d (YES), or when it is determined that Fmax=F0 is achieved in step S10e (YES), the power supply controller 29e displays a message that urges a user to replace the battery 38 in the picture display panel 14 in step S11a and terminates the processing (step S11g).

On the other hand, when it is determined that Tmin≧Tn−1 is not achieved in step S10a (NO), or when Fmax=F0 is not achieved in step S10e (NO), or after step S10c, the power supply controller 29e starts charging the battery 38 in step S11b and determines whether voltage V0 of the battery 38 has reached the full charge voltage Vmax in step S11c.

Moreover, the power supply control unit 29e waits until Vmax=V0 is achieved when it is determined that Vmax=V0 is not achieved (NO), the power supply controller 29e stops charging the battery 38 in step S11d and initializes discharge time T0 in step S11e when Vmax=V0 is determined to be achieved (YES), and then it increments the number of times of charge F0 of the battery 38 by +1 in step S11f and terminates the processing (step S11g).

According to the above-described embodiment, discharge time T0 of the battery 38 is actually measured, the battery 38 is determined to be new, when discharge time T0 is greater than or equal to the maximum value Tmax previously set in accordance with the discharge time of the new battery 38, and hence even the battery 38 that cannot be individually identified can be determined to have been replaced with a new battery.

Additionally, when the battery 38 is determined to be new, the number of times of charge F0 of the battery 38 is initialized, the number of times of charge is then counted every time the charge is performed, and hence even the battery 38 that cannot be individually identified can be replaced with a new battery, and then its number of times of charge F0 can be managed.

Further, when the thus counted number of times of charge F0 has reached the maximum value Fmax previously set as the number of times of charge that the battery 38 should be replaced, or when the actually measured discharge time T0 of the battery 38 is not greater than the minimum value Tmin previously set as the discharge time that the battery 38 should be replaced, a message that urges a user to replace the battery 38 is displayed. Therefore, a time for replacement of the battery 38 which cannot be individually identified can be easily managed.

Further, when it is determined that the battery 38 should be replaced, the supply of the power from the battery 38 can be forcibly interrupted, and the driving performed by the battery 38 can be stopped. As a result, it is possible to avoid occurrence of damage or malfunction of a device caused due to supply of abnormal power from the battery 38 that has reached the end of its life.

Here, in the foregoing embodiment, as discharge time T0 which is used for judging whether the battery 38 is new or should be replaced, a sum of discharge time T1 at the time of the DC drive and discharge time T3 at the time of a light load is used, and hence the battery 38 can be accurately managed.

However, discharge time T1 at the time of the DC drive alone may be used as discharge time T0 depending on an accuracy of management of the battery 38. Further, discharge time T1 at the time of the DC drive and discharge time T3 at the time of the AC drive are not added, but they can be compared with preset different reference values, respectively to determine whether the battery is new or whether the battery should be replaced, thereby further accurately managing the battery 38.

The various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A battery management apparatus comprising:
a time measurement module which is configured to measure a discharge time after requesting driving a device by a direct-current voltage supplied by a battery until an output voltage of the battery is reduced to a discharge stop voltage which is a voltage that the battery should stop discharge; and
a determination module which is configured to determine whether the battery is new, when the discharge time measured by the time measurement module is greater than or equal to a predetermined time set to determine that the battery is new.

2. The apparatus of claim 1, further comprising:
a light load time measurement module which is configured to measure a discharge time after requesting driving the device by an alternating-current voltage supplied from the outside until the output voltage of the battery is reduced to the discharge stop voltage.

3. The apparatus of claim 2, wherein
the light load time measurement module is configured to convert the measured discharge time into a discharge time when driving the device by the direct-current voltage supplied from the battery is requested and to output the converted time.

4. The apparatus of claim 3, wherein
the determination module is configured to determine that the battery is new, when a discharge time obtained by adding the discharge time measured by the time measurement module and the converted discharge time output from the light load time measurement module is greater than or equal to a predetermined time set to determine that the battery is new.

5. The apparatus of claim 4, further comprising:
a counting module which is configured to set the number of times of charge for the battery to an initial value and count the number of times of charge every time the battery is charged when the determination module determines that the battery is new.

6. The apparatus of claim 5, further comprising:
a notification module which is configured to notify that the battery is replaced when the number of times of charge counted by the counting module is greater than or equal to a predetermined number of times set to determine a time for replacement of the battery.

7. The apparatus of claim 5, further comprising:
a charger which is configured to charge the battery whose number of times of charge is set to the initial value by the counting module in a state that the output voltage is lowered to a charge start voltage.

8. The apparatus of claim 3, further comprising:
a notification module which is configured to notify that the battery is replaced when a discharge time obtained by adding the discharge time measured by the time measurement module and the converted discharge time output from the light load time measurement module is less than or equal to a predetermined time set to determine a time for replacement of the battery.

9. A battery management method comprising:
measuring a discharge time after requesting driving a device by a direct-current voltage supplied by a battery until an output voltage of the battery is lowered to a discharge stop voltage which is a voltage that the battery should stop discharge; and
determining that the battery is new, when the measured discharge time is greater than or equal to a predetermined time set to determine that the battery is new.
